(19) United States
(12) Patent Application Publication
(10) Pub. No.: US 2009/0032880 A1
(43) Pub. Date: Feb. 5, 2009

(54) METHOD AND APPARATUS FOR TUNABLE ISOTROPIC RECESS ETCHING OF SILICON MATERIALS

(75) Inventors: Mark Naoshi Kawaguchi, Sunnyvale, CA (US); Meihua Shen, Fremont, CA (US); Hiroki Sasano, Sunnyvale, CA (US); Rong Chen, Sunnyvale, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(73) Assignee: APPLIED MATERIALS, INC.

(21) Appl. No.: 11/833,481

(22) Filed: Aug. 3, 2007

(51) Int. Cl. H01L 29/94; H01L 21/302; H01L 21/311

(52) U.S. Cl. 257/369; 438/703; 438/710; 257/E29.345; 257/E21.214; 257/E21.246

(57) ABSTRACT

Methods and apparatuses to etch recesses in a silicon substrate having an isotropic character to undercut a transistor in preparation for a source/drain regrowth. In one embodiment, a cap layer of a first thickness is deposited over a transistor gate stack and spacer structure. The cap layer is then selectively etched in a first region of the substrate, such as a p-MOS region, using a first isotropic plasma etch process and a second anisotropic plasma etch process. In another embodiment, an at least partially isotropic plasma recess etch is performed to provide a recess adjacent to the channel region of the transistor. In a particular embodiment, the plasma etch process provides a recess sidewall that is neither positively sloped nor more than 10 nm re-entrant.

### BACKGROUND

1. Field

Embodiments described herein relate to the electronics manufacturing industry and more particularly to the etching of recesses in a substrate, such as one used in integrated circuit (IC) fabrication.

2. Discussion of Related Art

Locally strained silicon on p-MOS transistors has been found to improve carrier mobility up to 50% in 90 nm logic devices. Locally strained silicon generally entails removing a portion of the silicon substrate 101 about the gate stack of a p-MOS transistor, the gate stack having a gate dielectric 105, a gate electrode 106 and a gate hardmask 107. As shown in FIG. 1A, the recess 115 thereby undercuts the spacer 112. Subsequently, an epitaxial silicon-germanium allows (SiGe) source/drain 130 is grown in the recess 115, as shown in FIG. 1B. The SiGe induces a compressive uniaxial strain on the silicon under the gate stack which enhances hole mobility in the silicon channel of the p-MOS device.

Many constraints make the etch process used to remove a portion of the silicon substrate, referred to herein as the “recess etch,” particularly challenging. Specifically, the lateral proximity of the recess to the channel, D_{channel}, dramatically impacts the final stress on the channel and ultimately the carrier mobility. So too does the recess profile; as shown in FIG. 1A, the recess 115 has an undesirable “pinched” profile with the “ears” 116 that are a result of the recess profile being re-entrant by a distance, Dᵣₑ₋ₑₙₜᵣₐₙₜ. Other non-ideal profiles include those having a positive slope at the top of the recess nearest the gate stack (not shown). A positive slope is further characterized by the region immediately below the channel having the most undercut with the amount of undercut decreasing monotonically with increasing recess depth. Such positive slopes can be difficult to control and less reproducible across a substrate and between substrates.

Furthermore, the maximum depth of the recess, D_{recess}, is limited by the implanted well 117 having a depth only a few times the maximum distance to be laterally undercut by the recess etch, D_{undercut}. Therefore, the ratio of the vertical etch rate to lateral etch rate (or the “V/L” etch rate ratio) of the recess etch process must be appropriately targeted and tightly controlled to form the recess 115 with a satisfactory V/L ratio. Additionally, the extent of the substrate surface roughness 119, induced by the recess etch process, impacts the interface of the subsequently grown epitaxially SiGe.

Further constraints on the recess etch process include integration issues, such as, a general incompatibility between shallow trench isolation and epitaxial source/drain regrowth where the recess interfaces with the isolation 120, shown in FIG. 1A. Specifically, the dimple 122 may be formed as a result of corner rounding near shallow trench isolation (STI) during previous chemical mechanical polishing (CMP). Such corner rounding may advantageously improve stress and other properties of the isolation 120, however the dimple 122 may be disadvantageous during the subsequent epitaxial regrowth process of the SiGe source/drain 130. For example, the presence of the dimple 122 may locally modify the epi faceting growth and/or retard film growth. Furthermore, the dimple 122 being locally deeper than the remainder of the trench 115 may limit the depth of the recess 115 and cause higher leakage if the dimple 122 is allowed to break through the well 117. Thus, the etch process employed to form the recess 115 should at a minimum not exacerbate the dimple 122 and preferably reduce its depth.

There are also significant selectivity demands placed on the recess etch. For example, the etch process must not break through the hard mask 107 over the gate electrode 106, of the gate stack, as shown in FIG. 1A. Similarly, both the spacer liner 111 and the spacer 112, typically of distinct materials, must be sufficiently resistant to the recess etch process that the gate electrode 107 is not damaged by the recess etch process. This is particularly an issue when the gate electrode 107 comprises polysilicon, which would be rapidly etched under silicon recess etch process conditions.

Finally, as with most etch processes, microloading (i.e. pattern density dependent etch rate variations), etch rate uniformity across a substrate, and run to run repeatability can not be ignored in the development of a manufacturable recess etch process. Thus, because of these many constraints, an etch process capable of forming recesses in the substrate, such as the recess 115, may be considered the most difficult etch process in state of the art semiconductor manufacturing.

### SUMMARY

Recess etch methods and apparatuses are described herein. In particular embodiments, these methods may be employed to form recesses in a silicon substrate having an isotropic character to undercut a transistor in preparation for a source/drain regrowth. In one embodiment, an at least partially isotropic plasma recess etch is performed to provide a recess adjacent to the channel region of the transistor. In certain embodiments, the recess has a V/L ratio of between 1.1 and 2.2. In a particular embodiment, as shown in FIG. 4E, the plasma condition provides a recess having a sufficiently large top taper radius that the recess sidewall is not re-entrant by more than 10 nm. In other embodiments, at least a portion of the recess sidewall is substantially vertical (not having a positive or negative sidewall slope). As used herein, the term “substantially vertical” is used in reference to a condition in which the recess sidewall along a measurable distance is effectively parallel to the direction used herein to describe the depth of the recess, D_{recess} and effectively perpendicular to the “lateral” direction of D_{undercut}. Thus, it should be appreciated that the terms “substantially vertical,” “vertical” and “lateral” are not absolute, but rather are relative to the orientation of the substrate.

In one embodiment, a cap layer of a first thickness is deposited over a transistor gate stack and spacer structure. The cap layer is then selectively etched in one region of the substrate, such as a p-MOS region, using an isotropic plasma etch process to thin the cap layer. In one such embodiment, the isotropic plasma etch process includes exposing the cap layer to a plasma of a mixture of gases comprising tetrafluoromethane (CF₄) and oxygen (O₂) at a ratio of between 5 and 10, diluted with argon (Ar) at a pressure of between 10 mT and 30 mT and energized with a source power of between 500 W and 1500 W for a chamber adapted for a 300 mm substrate. Following the isotropic cap layer etch, the remaining thickness of the cap layer is then etched with an anisotropic etch process to expose the substrate in preparation for the recess etch. In one such embodiment, the anisotropic plasma etch process includes exposing the cap layer to a plasma of a mixture of gases comprising CF₄ and chlorine (Cl₂) at a flow rate ratio of between 0.5 and 2 at a pressure of between 4 mT and 10 mT and energized by a source power of between approximately 500 W and 1500 W for a chamber adapted for a 300 mm substrate. In another embodiment, the isotropic plasma etch process includes exposing the cap layer to a plasma of a mixture of gases having CF₄ and trifluoromethane (CHF₃) at a flow rate ratio of between 0.5 and 2 at a pressure of between 10 mT and 30 mT and energized with a source power of between 500 W and 1500 W.

In a further embodiment, the isotropic plasma recess etch process includes exposure of the substrate to a plasma of a mixture of gases comprising nitrogen trifluoride (NF₃), Cl₂, and O₂. In another embodiment, the isotropic plasma process includes exposure of the substrate to a plasma of a mixture of gases comprising NF₃, Cl₂ and O₂ diluted with Ar or helium (He) at a pressure of between 10 mT and 30 mT and energized with a source power of between approximately 500 W and 1000 W. In one exemplary implementation, the NF₃ to Cl₂ flow rate ratio is between 0.5 and 1 mixed with 0 to 15 standard cubic centimeters/minute (sccm) O₂ and 200 sccm to 500 sccm Ar.

### BRIEF DESCRIPTION OF THE DRAWINGS

Embodiments are illustrated by way of example, and not limitation, in the figures of the accompanying drawings in which:

FIGS. 1A-1B illustrate a conventional recess etch.

FIGS. 2A-2B illustrate simulations describing relationships between the proximity and profile of recess sidewall and the transistor channel carrier mobility.

FIG. 3 illustrates a flow chart of a method for etching a recess in a substrate in accordance with a particular embodiment.

FIGS. 4A-4E illustrate cross sectional views of a recess etch method in accordance with one embodiment.

FIGS. 5A-5B illustrate process effects tables for various process parameters for a cap layer etch and silicon recess etch, respectively, in particular embodiments.

FIG. 6 illustrates a schematic of a deposition chamber employed in a particular embodiment.

### DETAILED DESCRIPTION

Embodiments of recess etch methods are described herein with reference to figures. However, particular embodiments may be practiced without one or more of these specific details, or in combination with other known methods, materials, and apparatuses. In the following description, numerous specific details are set forth, such as specific materials, dimensions and processes parameters etc. to provide a thorough understanding. In other instances, well-known semiconductor processes and manufacturing techniques have not been described in particular detail to avoid unnecessarily obscuring the claimed subject matter. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment. Furthermore, the particular features, structures, materials, or characteristics may be combined in any suitable manner in one or more embodiments.

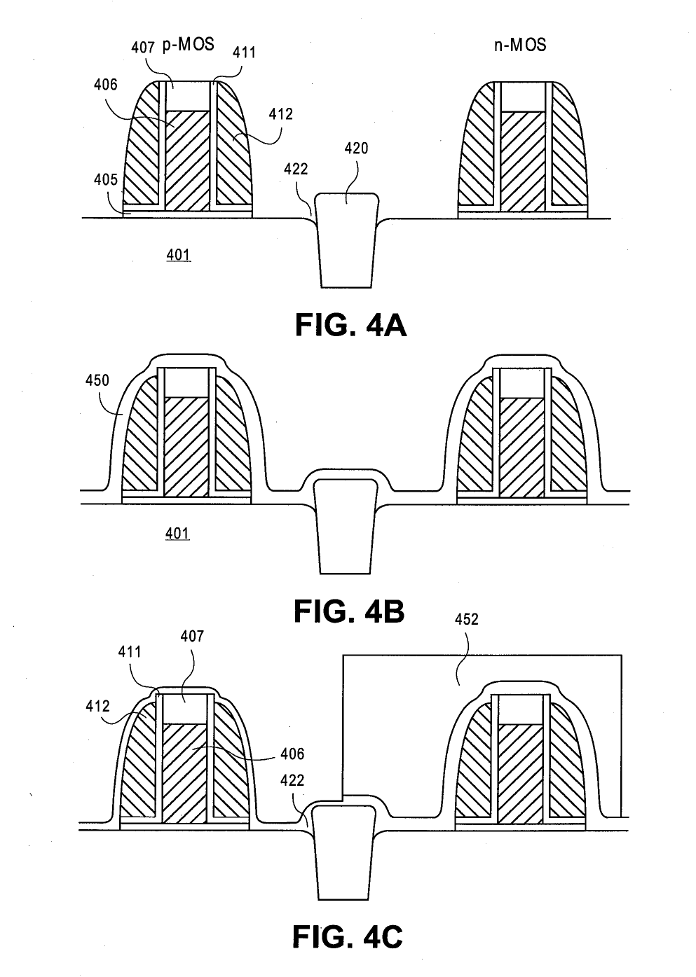

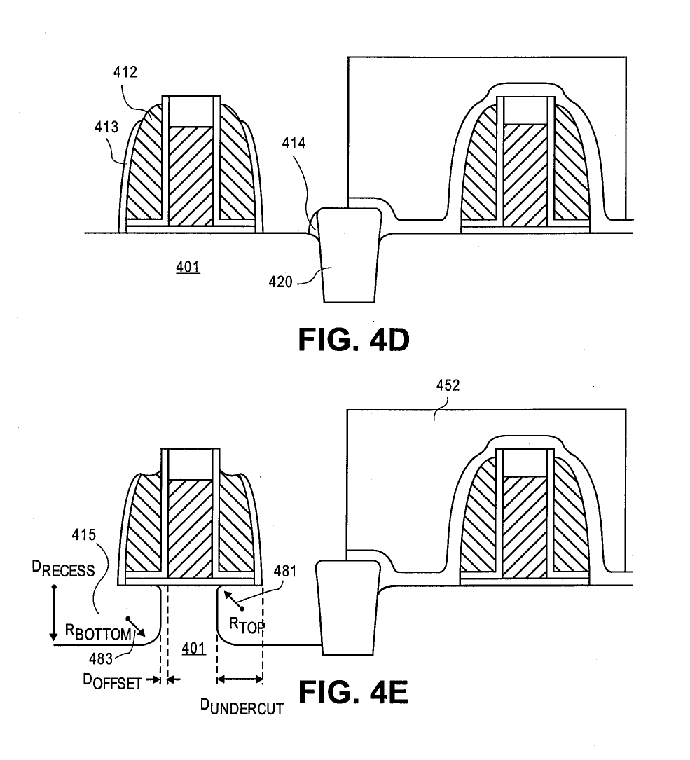

In certain embodiments, a substrate is exposed to a plasma condition to etch a recess in the substrate. In particular embodiments, the recess formed has geometry advantageous for the creation of controlled and repeatable stress in the channel of a transistor. In a particular embodiment, the plasma conditions described herein provide a recess under cutting a mask by an amount, D_{undercut} that is at least 30%, and preferably 40%, of the recess depth, D_{recess}. In particular embodiments, the V/L ratio of the recess is between 1.1 and 2.2. In one embodiment, the recess geometry resulting from the etch processes described herein advantageously ensures at least a portion of the recess sidewall is vertical rather than positively or negatively sloped. In an embodiment, as shown in FIG. 4E, the plasma conditions described herein provide a recess that is re-entrant by less than 10 nm and preferably less than 75 Å. In one such embodiment, at least the upper 25% of the recess depth, D_{recess}, as measured from the gate electrode into the substrate, is substantially vertical. In another embodiment, the plasma condition provides a recess having only a profile having a top taper radius 481 that is smaller than the bottom taper radius 483 with a least a portion of the recess being vertical where the top taper meets the bottom taper. In an embodiment, the top taper radius 481 is smaller than the bottom taper radius 483 with the bottom taper radius 483 being less than 50% of the recess depth D_{recess}. In one such embodiment, the bottom taper radius 483 is less than 35 nm and the top taper radius is less than 25 nm. In a further embodiment, at least the upper 25% of the recess depth, D_{recess}, as measured from the gate electrode into the substrate, is offset from an edge of a transistor gate electrode by a distance, D_{offset}, that is less than 20 nm.

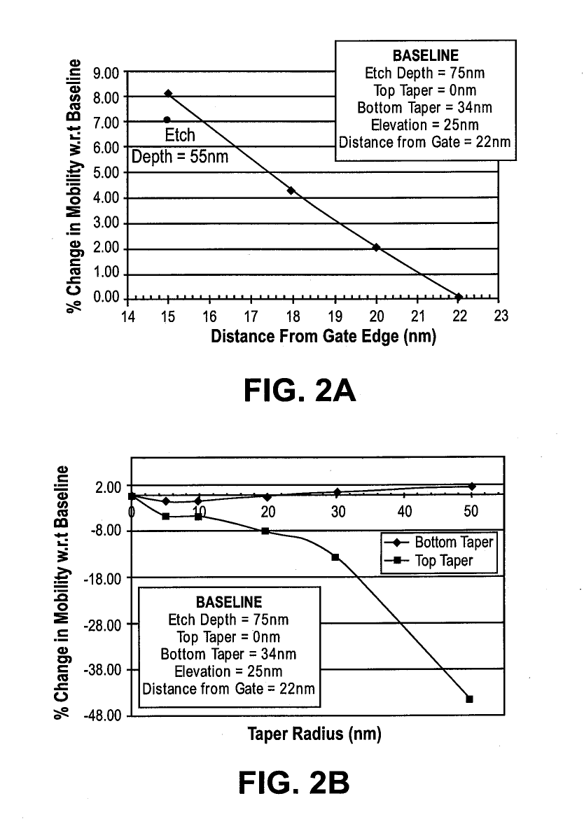

FIG. 2A depicts an exemplary simulation of the effect of distance, D_{offset}, between the recess sidewall and transistor channel on the hole mobility within a silicon channel in a p-MOS transistor having SiGe source drains epitaxially grown in the recess. The curve of FIG. 2A has been normalized to a recess having a vertical etched depth, D_{recess}, of 75 nm and a D_{channel} of 22 nm. The D_{recess} is dependent on technology node, such as 65 nm, however the trend shown in FIG. 2A should generally remain. For the particular example shown here, the mobility increases by approximately 1% for every 1 nm reduction in offset from the gate electrode.

Furthermore, the recesses modeled in FIG. 2A and FIG. 2B include consideration of the effect of a “lagging” etch immediately below the channel which may be characterized as a top taper radius of the recess, such as the top taper radius 481 in FIG. 4E. As modeled in FIG. 2A, the top taper radius is 0 nm, which is equivalent to a vertical recess sidewall having no lagging. The recess is similarly modeled in FIG. 2A to have a bottom taper radius of 34 nm. As so defined, the greater the top taper radius, the more the recess sidewall becomes re-entrant and the greater the bottom taper radius, the more the recess sidewall becomes positively sloped. Thus, for the modeled recess having a 75 nm D_{recess}, the upper ˜40 nm of the recess (75 nm-34 nm), or approximately the upper 50% of the recess has a substantially vertical profile shape. Such a profile is advantageous for good mobility control because the mobility is such a strong function of the D_{offset}.

As further shown in FIG. 2B, depicting a simulation of the effect of the recess profile on the hole mobility within the silicon channel, the mobility is only a weak function of bottom taper radius, while the mobility is a very strong function of top taper radius. This is likely because the majority of the carrier current occurs in a region of the silicon substrate proximate to the gate electrode. Thus, it should be appreciated that as the bottom radius approaches the depth of the recess and therefore begins to impact the silicon substrate proximate to the gate electrode, the effect of the bottom taper radius on carrier mobility should become greater. While FIG. 2 serves to illustrate the importance of both the recess proximity and the recess profile, it should be appreciated that FIG. 2 is merely an example and the various assumptions made in the model is readily adapted other transistor structural parameters.

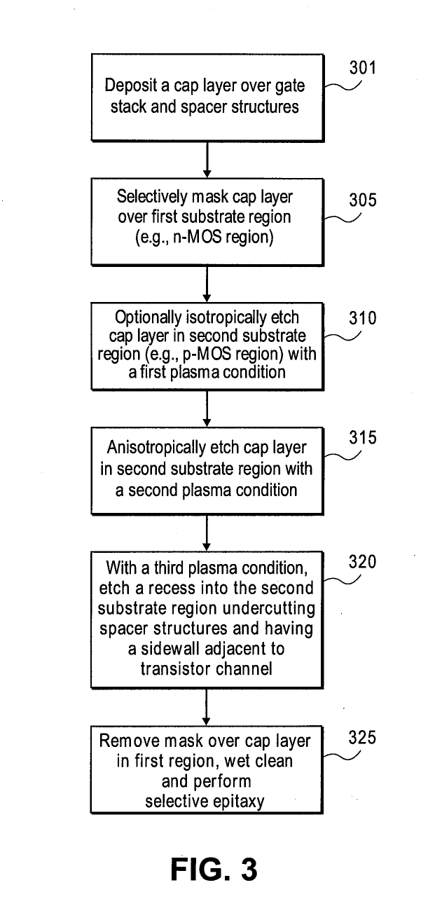

FIG. 3 is a flowchart depicting an embodiment of a method of etching a recess, such as that exemplary recess modeled in FIG. 2, in a first region of a substrate, such as a p-MOS region in a silicon substrate. As shown, the method begins with the deposition 301. The deposition 301 forms a cap layer over transistor gate stack and over spacer structures adjacent to the gate stack. Following the deposition 301, the cap layer is selectively masked at the operation 305 with a lithographic process. In an embodiment, the mask is lithographically formed over a second region of the substrate, such as an n-MOS region of a CMOS integrated circuit (IC). Next, the unmasked portion of the cap layer may be isotropically etched with a first plasma etch condition at the operation 310. At the operation 315, the unmasked portion of the cap layer may be anisotropically etched with a second plasma condition to expose the first region of the substrate. The method further includes the operation 320, where a recess is etched into the first region of the substrate. In an embodiment, the recess undercuts at least a portion of the spacer structures adjacent to the p-MOS transistor gate stack. After the recess is formed in the first region of the substrate, the recess etch method is substantially complete and subsequently, at the operation 325, any lithographic mask remaining on the cap layer in the second region of the substrate may be removed. The recess in the first region is ultimately cleaned and filled, such as by a selective SiGe epitaxy process which does not deposit material on the cap layer remaining in the second region. FIGS. 4A-4E illustrate cross-sectional views of a workpiece fabricated with an exemplary implementation of the method in the flowchart of FIG. 3 and is described in further detail.

Referring to FIG. 4A, two regions of a substrate 401 are employed to fabricate a CMOS IC, with a p-MOS transistor in a first region of the substrate 401 and a n-MOS transistor in a second region of the substrate 401. In one embodiment, the substrate 401 is a semiconductor wafer, such as, but not limited to monocrystalline silicon, germanium, or a commonly known III-V compound semiconductor material. In another embodiment, the supporting substrate is a glass, such as used in the manufacture of thin film transistors for displays. In still other embodiments, the support is quartz, sapphire or other insulative material. Embedded in the substrate 401 is an isolation region 420. Isolation region 420 may be any commonly employed material capable of electrically isolation the p-MOS transistor in first region of substrate 401 from the n-MOS transistor in the second region of substrate 401. The isolation region 420 may be formed by commonly employed fabrication techniques, such as STI. In a particular embodiment, the STI process causes a “dimple” 422 in the substrate 401, as elsewhere discussed herein.

Generally, the p-MOS transistor formed in the first region of substrate 401 may be of any design known in the art, such as but not limited to, planar field effect transistor (FET), non-planar FET (e.g. multi-gate devices) and metal semiconductor FET (MESFET). In the embodiment shown, the planar p-MOS transistor further includes a hard mask 407 on a gate electrode 406, over a gate oxide 405. The gate oxide 405 may comprise any conventional dielectric, such as, but not limited to silicon dioxide, silicon nitride or silicon oxynitride. The gate oxide 405 may further comprise a dielectric having a higher dielectric constant, such as, but not limited to, hafnium silicates and/or oxides (e.g. HfSiON.HfO₂ and HfSiO) and zirconium silicates and/or oxides. The gate electrode 406 may similarly comprise any commonly employed material, such as doped polysilicon with metal silicides, or metals such as tantalum, nickel, titanium, tungsten, aluminum, cobalt, their silicides and their nitrides. The hard mask 407 may comprise commonly employed dielectrics, such as, but not limited to, silicon dioxide, silicon nitride, silicon oxynitride. In alternate embodiments, the hardmask 407 may comprise commonly employed metals, as well as their silicides and their nitrides.

A spacer liner 411 and a spacer 412 is adjacent to the gate electrode 406 and hardmask 407. The spacer liner 411 and spacer 412 may be of materials commonly used in the industry for transistor spacer structures, such as, but not limited to silicon nitride and silicon dioxide. In a particular implementation, the spacer liner 411 is a silicon dioxide form by conventional means while the spacer 412 is a low temperature, bis(tertiary-butylamino)silane (BTBAS) nitride or oxynitride.

As shown in FIG. 4B, a cap layer 450 is then deposited at operation 301 over both the first and second region of the substrate 401, covering the p-MOS and n-MOS devices. The cap layer 450 is of a material and with a thickness adequate to block an epitaxy process subsequently employed. The cap layer 450 may be of any material which can be selectively removed from the first region of the substrate 401 without detriment to the p-MOS transistor and can also withstand the epitaxy temperatures. In an embodiment, cap layer 450 comprises a dielectric material, such as silicon dioxide, silicon nitride, diamond-like carbon (DLC). In another embodiment, cap layer 450 is a metal, perhaps one useful for forming a silicide in the source/drain regions of an n-MOS transistor, such as, but not limited to, cobalt, vanadium, nickel, and titanium. The cap layer 450 may be deposited by any commonly known technique, such as but not limited to, chemical vapor deposition (CVD), plasma enhanced CVD (PECVD) and physical vapor deposition (PVD). The as-deposited thickness of the cap layer 450 is dependent on the pre-clean process employed just prior to the subsequent epitaxy of the source/drain regions. In certain embodiments, the cap layer 450 is a silicon oxide deposited to a thickness between 100 Å and 300 Å.

With the cap layer 450 deposited, a mask 452 may be selectively formed of the region of the substrate which is not to include a recess, such as the n-MOS region depicted in FIG. 4C. Selective formation of the mask 452 may proceed by any commonly known technique including lithography of a photoresist layer and/or additional hard mask layer, such as DLC.

After the cap layer 450 is selectively masked, the cap layer 450 in the unmasked regions may then be removed to expose the substrate in preparation for the recess etch. In certain embodiments, the cap layer 450 is first isotropically etched, as further shown in FIG. 4C, to thin or clear the cap layer 450. In particular embodiments where the cap layer 450 is isotropically thinned, an anisotropic etch is then employed to clear the cap layer 450. It should be appreciated that the isotropic etch of the cap layer is optional and so alternate embodiments may employ only an anisotropic cap layer etch.

In particular embodiments employing the isotropic etch shown in FIG. 4, the thickness of the cap layer spacers may be advantageously reduced. While a cap layer thickness of approximately 300 Å may provide good margin ensuring at least some (e.g. ˜25 Å) of the cap layer 450 survives the epitaxy pre-clean process, such a thickness can result in the formation of a wide cap layer spacer adjacent to the previously existing spacer structure (e.g. spacer 412) if the cap layer 450 is only anisotropically etched. For given width of spacer liner 411 and spacer 412, a wide cap layer spacer disadvantageously decreases the amount of undercut, D_{undercut}, the subsequent recess etch can achieve, limiting the mobility gain as shown in FIG. 2. For example a 300 Å cap layer, if conformally deposited, may produce a 300 Å wide spacer and thereby increase by 300 Å the distance between D_{undercut} and the transistor channel (i.e. D_{offset}) for a given recess etch process. To account for this increase in D_{offset}, the recess etch must have a greater D_{undercut}, or smaller recess V/L ratio. The recess V/L ratio characterizes the degree of isotropy of the recess and is the ratio of the maximum recess depth, D_{recess}, to the maximum D_{undercut}. A recess with very low V/L ratio, such as unity, is a significant constraint on the recess etch process and therefore it is advantageous to be able to reduce D_{undercut} (or increase the V/L ratio). Thus, the increase in D_{offset} resulting from the presence of the cap layer 450 should be minimized to facilitate reducing the degree of isotropy required of the recess etch.

The isotropic etch may be performed by any technique known in the art for the particular cap layer material. The isotropic etch should be capable of thinning the cap layer 450 in all geometries with good control. In a particular embodiment employing an oxide cap layer 450, a commonly known wet etch comprising hydrofluoric acid (HF) may be performed to isotropically thin the cap layer 450 or to completely remove it. However, in certain embodiments where geometry or other constraints prevent the use of wet etchants, a plasma etch process may be employed to thin the cap layer 450.

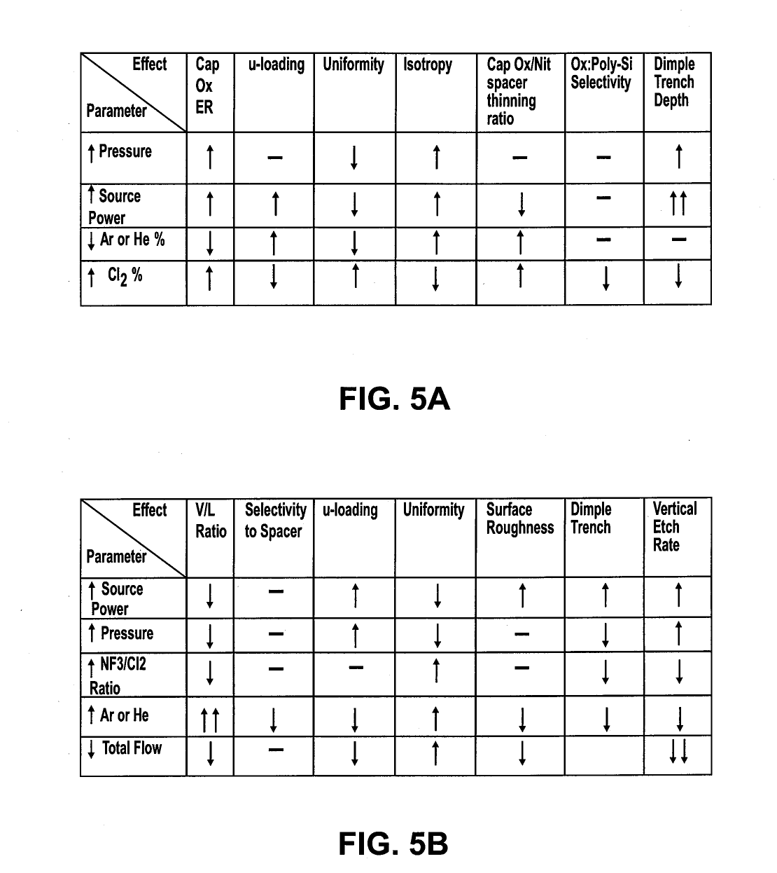

In particular embodiments, the isotropic plasma etch process includes exposing a substrate to a plasma of a mixture of gases comprising fluorine source, such as CF₄. While other fluorine gases, such as sulfur-hexafluoride (SF₆), NF₃, CHF₃, and difluoromethane (CH₂F₂) can be used as well or in combination, CF₄ embodiments advantageously provide a sufficiently low oxide etch rate (ER) that the cap layer 450 may be controllably thinned or removed without the risk of clearing the hardmask 407, liner 411 or spacer 412, all of which are to be avoided to prevent subsequent attack of the gate electrode 406 during the recess etch or the formation of polysilicon bumps during the subsequent epitaxy process. FIG. 5A depicts a table for certain advantageous embodiments of the plasma etch method employing gas mixtures comprising CF₄, energized in an inductively coupled plasma etcher. The effects characterized in FIG. 5A include the ER of the cap layer oxide, microloading, uniformity across the substrate, degree of isotropy, the amount the cap oxide is thinned over the amount a nitride spacer 412 is etched, the cap oxide to poly-silicon selectivity and the impact of the cap layer etch on the dimple 422. The responses provided in FIG. 5A are relative to a particular embodiment having a plasma etch condition for isotropic cap layer etch that includes CF₄ and O₂ at a flow rate ratio of between 5 and 10 CF₄:O₂, diluted with Ar, at a pressure of between 10 mT and 30 mT and energized with a source power of between 500 W and 1500 W for a chamber adapted for a 300 mm substrate. In one particular embodiment, the bias power is 0 W. In further embodiments, bias power is no more than 20% of the source power. Such processes provide a relatively low cap oxide ER of around 200 A/min, display some microloading with respect to the lateral cap oxide ER and have uniformities characterized by a 1 sigma of 5%-8%. Isotropy is relatively high, however the selectivity to the oxide cap layer 450 over the nitride spacer 412 is relatively low. The dimple depth may also be slightly aggravated because the isotropic removal of the cap layer spacer 414 may mitigate a tendency for the cap spacer to protect the substrate dimple formed during the STI process. The effects of increasing pressure and power, as well as decreasing the fraction of Ar (or other dilution gas, such as He) are shown in rows one, two, and three of FIG. 5A, respectively. Of particular note is the increase in dimple depth with increasing source power.

Following the isotropic cap layer etch, in the embodiment depicted in FIG. 4D, the remaining thickness of cap layer 450 is then etched with an anisotropic etch process to expose the substrate 401 in preparation for the recess etch. As shown in FIG. 4D, the anisotropic cap layer etch produces a cap layer spacer 413. The cap layer spacer 413 advantageously protects the nitride spacer 412, which may be particularly susceptible to attack during a subsequent recess etch, such as in embodiments employing BTBAS. Thus, both the isotropic etch and anisotropic etch combine to provide a protective cap layer spacer 413 of reduced lateral thickness or “width” (as measured from a point on the sidewall of the spacer 412 to the nearest point on the sidewall surface of the cap layer spacer 413). This reduced cap layer spacer 413 width thereby relaxes the V/L ratio constraint on the recess etch. In a particular embodiment, the isotropic etch and anisotropic etch combine to provide a protective cap layer spacer 412 that has a thickness on the sidewall of the spacer 412 that is less than 50% of the as-deposited thickness of the cap layer 450 remaining on the second region of the substrate (e.g. an n-MOS region). In another particular embodiment, the isotropic etch and anisotropic etch combine to provide a protective cap layer spacer 412 that has a thickness on the sidewall of the spacer 412 that is less than 30% of the as-deposited thickness of the cap layer 450. While the isotropic cap layer etch followed by the anisotropic cap layer etch provides for a first thinning of the cap layer and a subsequent cap layer spacer formation, in certain alternative embodiments, an anisotropic cap layer etch may precede an isotropic cap layer etch to first form a cap layer spacer and then thin the lateral dimension of cap layer spacer.

In one embodiment, the anisotropic plasma etch process includes exposing the oxide cap layer 450 to a plasma of a mixture of gases comprising CF₄ and Cl₂. In one such embodiment, the etch process conditions further include CF₄ and Cl₂ having a flow rate ratio of between 0.5 and 2 at a pressure of between 4 mT and 10 mT and energized by a source power of between approximately 500 W and 1500 W and a bias power of no greater than 80 W for a chamber adapted for a 300 mm substrate. Row four of FIG. 5A describes the effects of such a CF₄/Cl₂ process relative to the CF₄/O₂/Ar isotropic cap layer etch embodiments previously described herein. As shown, with increasing Cl₂ fraction the cap oxide ER is increased, to approximately 700 Å/min for an oxide cap layer. The ER uniformity is also advantageously improved, characterized by a 1 sigma of approximately 2%. Furthermore, the addition of Cl₂ reduces the depth of the dimple after the subsequent recess etch. This particular CF₄/Cl₂ process embodiment also displays relatively less microloading than the isotropic cap layer etch embodiments and becomes anisotropic and provides a selectivity of ˜0.5 to poly-silicon. Because of the lower selectivity, a recess will begin to form in the substrate 401 during the over etch of the cap layer 450.

In still other embodiments, the anisotropic cap layer etch process includes exposing an oxide cap layer to a plasma of a mixture of gases having CF₄ and CHF₃ at a flow rate ratio of between 0.5 and 2 at a pressure of between 10 mT and 30 mT and energized with a source power of between 500 W and 1500 W and a bias power of no more than 80 W. Without Cl₂, the dimple depth becomes somewhat worse than CF₄/Cl₂ process embodiments, however, the selectivity of the etch process to the oxide cap layer 450 relative to the substrate 401 becomes significantly greater than 2:1. Microloading with the CF₄/CHF₃ process embodiments is also minimized. Thus, a plasma of CF₄ may be modified with the addition of CHF₃ or Cl₂, as described, depending on the importance of dimple depth.

Following the removal of the cap layer 450, the recess 415 is formed in the substrate 401, as shown in the embodiment depicted in FIG. 4E. In certain embodiments, the recess 415 is formed by exposing the substrate 401 to a plasma etching condition. The recess etch may consist of one primary step or a combination of steps, such as a relatively slow anisotropic etch and an isotropic etch. An isotropic plasma etching condition may be provided for a silicon substrate 401 with a gas mixture including an isotropic etching gas from a neutral species precursor like NF₃, CF₄ and SF₆, an ion-enhanced species precursor and/or passivating gas, such as O₂, Cl₂, CHF₃, and hydrogen bromide (HBr), and a dilution gas, such as Ar, He and xenon (Xe). Particular embodiments employ NF₃ for a relatively smaller V/L ratio, smoother surface and lower vertical ER relative to SF₆. Similarly, embodiments utilizing NF₃ have a relatively higher selectivity to the spacer 412 and hard mask 407 than recess etch chemistries employing CF₄.

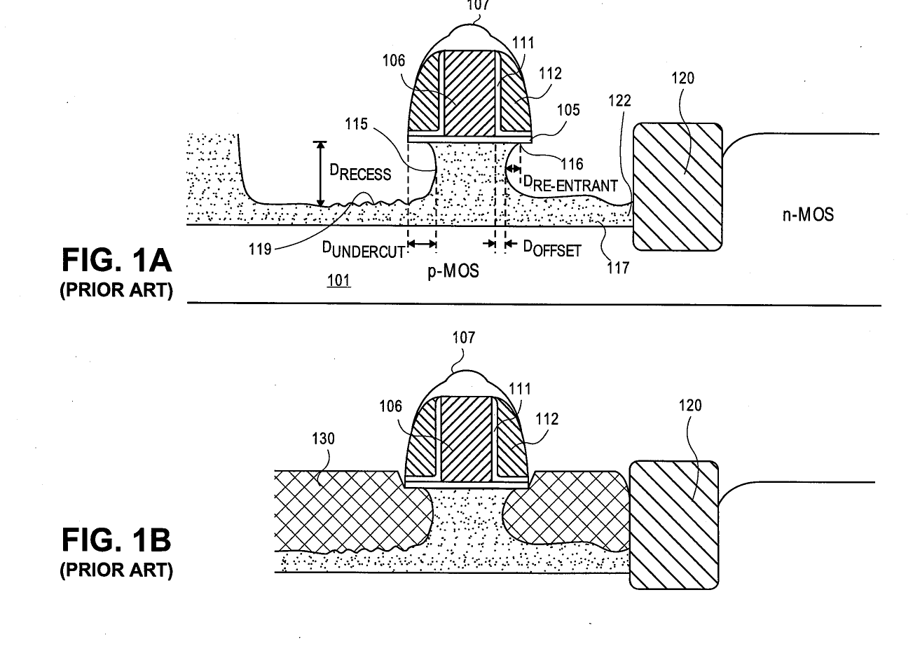

Certain plasma recess etch embodiments further include Cl₂. Cl₂ advantageously provides a relatively smaller V/L ratio than does HBr. Thus, while NF₃/HBr embodiments may prove adequate for certain applications permitting a larger V/L ratio, such as 65 nm and 90 nm, NF₃/Cl₂ is advantageous for the more aggressively scaled applications, such as sub-65 nm technologies. FIG. 5B depicts an effects table for certain advantageous embodiments of the plasma etch method employing gas mixtures comprising NF₃ and Cl₂ across power and pressure adjustments as well as gas mixtures further including a dilution gas. Here, the effects or responses characterized include: V/L ratio, characterizing the isotropic nature of the etch process, the selectivity of the recess etch process to the spacer 412, microloading, uniformity, surface roughness of the recess, the dimple depth, and the vertical ER. As shown in the table of FIG. 5B, the ratio of the etching gas (e.g. NF₃) to the passivating gas (e.g. Cl₂) has an effect on both the V/L ratio and microloading. Of note is the V/L ratio decreases with increasing pressure. In particular, between approximately 4 mTorr and 12 mTorr, the V/L ratio decreases linearly from about 2.2 to 1.1. Balancing of the etchant and passivating gas fractions also has a large effect on recess profile shape. Specifically, avoidance of the pinched profile characterized by the “ear” 116 in FIG. 1A is dependent on this balance between etchant gas and passivation gas fractions. Thus, in certain embodiments, the etchant gas mixture includes NF₃ and Cl₂ having a flow rate ratio of between 0.5 and 1.

Increasing the dilution gas partial pressure, on the other hand, may result in an a substantial increase in the V/L ratio, but advantageously reduces roughness, microloading, surface roughness, dimple depth and the vertical ER while also improving uniformity. In a particular embodiment, Ar is employed in preference to He for providing a slightly smaller V/L ratio. Thus, in particular embodiments, the recess etch process employs a gas mixture comprising NF₃, Cl₂ and Ar. In one such embodiment, the Ar flow rate is between 1 and 3 times greater than the combined flowrate of NF₃ and Cl₂.

Within a subset of the conditions described herein, a further addition of a small partial pressure of O₂ has the beneficial effect in the etch chemistry of improving the selectivity of the silicon recess etch to the spacer 412, particularly for a nitride spacer. Thus, in a particular embodiment, the recess etch employs a gas mixture comprising less than 200 sccm of NF₃ and Cl₂ at a flow rate ratio of between 0.5 and 1, a dilution gas of Ar, and between 5 sccm and 15 sccm O₂.

A reduced total flow rate of a gas mixture comprising NF₃/Cl₂/O₂/Ar advantageously reduces the vertical etch rate significantly (thereby providing better recess depth control), reduces surface roughness, improves uniformity and reduces microloading while also advantageously reducing the V/L ratio. Therefore, in particular embodiments, the total flow is limited to less than approximately 300 sccm. In one such embodiment, the gas mixture comprises between 25 and 50 sccm NF₃, 25 and 50 sccm Cl₂, 5 and 10 sccm O₂ and 100 to 225 sccm Ar.

As also shown in FIG. 5B, increasing the pressure of the gas mixture reduces the V/L ratio at the expense of greater microloading, poorer uniformity, a deeper dimple and a higher vertical etch rate. Thus, in certain embodiments employing a gas mixture comprising less than 200 sccm NF₃ and Cl₂ at a flow rate ratio of between 0.5 and 1, Ar at flow rate 1-3 times that of NF₃ and Cl₂, and between 5 sccm and 15 sccm O₂, the etch process pressure is controlled to between 4 mT and 30 mT with particularly favorable embodiments employing a gas mixture comprising between 25 and 50 sccm NF₃, 25 and 50 sccm Cl₂, 5 and 10 sccm O₂ and 100 to 300 sccm Ar at a pressure of between 15 mT and 20 mT.

In further embodiments, the plasma etch condition is provided from a gas mixture comprising NF₃, O₂, Cl₂ and a dilution gas, such as Ar or He, energized with a source power of between 500 W and 1500 W. As shown in FIG. 5B, increases in source power are advantageous predominantly for the greater undercut possible, reducing the V/L ratio. The other responses degrade with increased source power. Notably, the vertical etch rate becomes very high rendering control of a shallow etch more difficult. Similarly, both the V/L ratio and the vertical etch rate increases with increasing bias power. Thus, the bias power is less than 80 W in certain embodiments and is 0 W in a particular embodiment. For these reasons, particular embodiments forming the recess 415 of FIG. 4E employ a gas mixture comprising NF₃, O₂, Cl₂ and a dilution gas energized with a source power of between 500 W and 1000 W for a chamber adaptable to a 300 mm substrate. One such embodiment employs a gas mixture of less than 200 sccm of NF₃ and Cl₂ at a flow rate ratio of between 0.5 and 1, an Ar at flow rate 1 to 3 times that of NF₃ and Cl₂, and between 5 sccm and 15 sccm O₂ controlled to a pressure between 15 mT and 20 mT energized with a source power of between 600 W and 800 W to etch the recess 415 into the silicon substrate 401 to a depth of approximately 650 Å while undercutting a mask by at least 300 Å. Other embodiments provide for a recess with a V/L ratio between about 1.1 and 2.2. Furthermore, such an embodiment may provide a recess with the desired profile shape. As previously discussed herein, at least a portion of the recess sidewall is not positively sloped and at least a portion of the recess sidewall is substantially vertical. The upper-most portion of the recess may further be described as having a non-re-entrant or only slightly re-entrant profile characterized as having a top corner with a radius of curvature, Rₜₒₚ that is smaller than the radius of curvature at the bottom corner, R_{bottom}. The “slightly re-entrant” profile in particular embodiments being re-entrant by less than 10 nm and preferably less than 75 Å, as previously described herein.

Returning to the flowchart in FIG. 3, after the formation of the recess etch in operation 320, the mask 452 may be removed and the recess 415 subsequently wet cleaned or dry cleaned in preparation for an epitaxial growth of source/drain regions in the recess 415. In a particular embodiment, SiGe is grown in the recess 415 to fabricate a strained p-MOS silicon transistor.

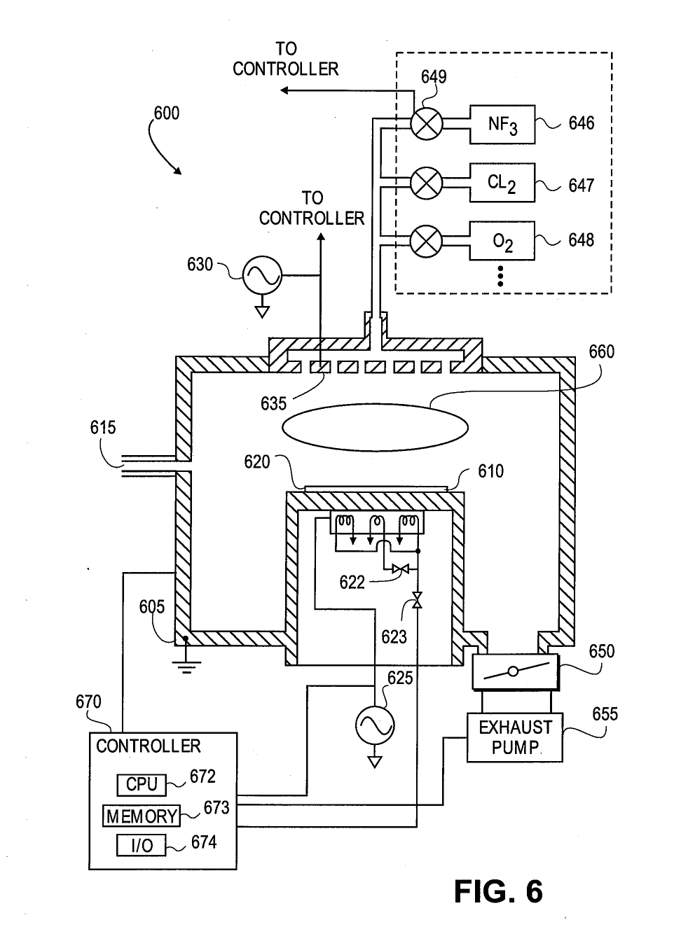

In an embodiment, certain processes of etch method depicted in FIG. 3 are performed in an etch process chamber, such as the AdvantEdge G3, manufactured by and commercially available from Applied Materials of CA, USA. It is to be understood that other etch chambers can also be used. A cross-sectional view of an exemplary etch chamber 600 is shown in FIG. 6. Etch chamber 600 includes a process chamber 605. A substrate 610 is loaded through an opening 615 and placed on a temperature controlled chuck 620. Chuck 620 may be temperature controlled with a dual-zone helium cooling system, wherein valve 622 regulates backside helium pressure independently from valve 623 to improve wafer temperature tuning to offer both a greater range of center-to-edge thermal gradients and better temperature uniformity.

Process gases, such as NF₃, Cl₂, O₂, are provide to process chamber 605 in an embodiment of the recess etch method previously described herein. The process gases are supplied from sources 646, 647 and 648, respectively, contained within a gas panel 641. The process gases are supplied from the source through respective mass flow controllers 649 to the interior of the process chamber 605. Other gases, such as CF₄, He and Ar, may further be provided (not shown). Process chamber 605 is evacuated via an exhaust valve 650 connected to a high capacity vacuum pump stack 655.

Coil 635 and chuck 620 form a pair of electrodes. When radio frequency (RF) power is applied, process gas within process chamber 605 is ignited by the fields formed between the pair of electrodes to form plasma 660. Generally, an electric field is produced by coupling chuck 620 to a source 625 of single or double frequency RF. Alternatively, RF source 630 may be coupled to coil 635 or both RF sources 630 and 625 may be employed. Coil 635 may further be a tunable dual-coil source.

In one embodiment, etch chamber 600 is computer controlled by controller 670 to control the RF power, gas flows, pressure, chuck temperature, as well as other process parameters. Controller 670 may be one of any form of general-purpose data processing system that can be used in an industrial setting for controlling the various subprocessors and subcontrollers. Generally, controller 670 includes a central processing unit (CPU) 672 in communication with memory 673 and input/output (I/O) circuitry 674, among other common components. Software commands executed by CPU 672, cause etch chamber 600 to first plasma etch a cap layer isotropically, plasma etch the cap layer anisotropically, and then plasma etch a recess in the substrate. In one such embodiment, software commands executed by CPU 672, cause etch chamber 600 to etch approximately 650 Å of silicon under cutting a mask by at least 300 Å using a partially isotropically etching plasma comprising a gas mixture of less than 200 sccm of NF₃ and Cl₂ at a flow rate ratio of between 0.5 and 1, Ar at flow rate 1 to 3 times that of NF₃ and Cl₂, and between 5 sccm and 15 sccm O₂ controlled to a pressure between 15 mT and 20 mT while a source power of between 600 W and 800 W is applied to provide a plasma. In one such embodiment the gas mixture comprises between 25 and 50 sccm NF₃, 25 and 50 sccm Cl₂, 5 and 10 sccm O₂ and 100 to 225 sccm Ar.

Portions of the present invention may be provided as a computer program product, which may include a computer-readable medium having stored thereon instructions, which when executed by a computer (or other electronic devices), cause a process chamber to first plasma etch a cap layer isotropically, plasma etch the cap layer anisotropically, and then plasma etch a recess in the substrate. In other embodiments, a computer-readable medium has stored thereon instructions, which when executed by a computer (or other electronic devices), cause a process chamber to etch approximately 650 Å of silicon under cutting a mask by at least 300 Å using a partially isotropically etching plasma comprising a gas mixture of less than 200 sccm of NF₃ and Cl₂ at a flow rate ratio of between 0.5 and 1, Ar at flow rate 1 to 3 times that of NF₃ and Cl₂, and between 5 sccm and 15 sccm O₂ controlled to a pressure between 15 mT and 20 mT while a source power of between 600 W and 800 W is applied to provide a plasma. In one such embodiment the gas mixture comprises between 25 and 50 sccm NF₃, 25 and 50 sccm Cl₂, 5 and 10 sccm O₂ and 100 to 225 sccm Ar. The computer-readable medium may include, but is not limited to, floppy diskettes, optical disks, CD-ROMs (compact disk read-only memory), and magneto-optical disks, ROMs (read-only memory), RAMs (random access memory), EPROMs (erasable programmable read-only memory), EEPROMs (electrically-erasable programmable read-only memory), magnet or optical cards, flash memory, or other commonly known type computer-readable medium suitable for storing electronic instructions. Moreover, embodiments of the present invention may also be downloaded as a computer program product, wherein the program may be transferred from a remote computer to a requesting computer by way of a wire.

Although these embodiments have been described in language specific to structural features and/or methodological acts, it is to be understood that the invention defined in the appended claims is not necessarily limited to the specific features or acts described in particular embodiments. The specific features and acts disclosed are to be understood as particularly graceful implementations of the claimed invention in an effort to illustrate rather than limit the present invention.

What is claimed is:

1. A method of forming a transistor source/drain recess comprising:
forming a first transistor gate stack and adjacent spacer in a first region of a substrate and a second transistor gate stack and adjacent spacer in a second region of the substrate;
depositing a cap layer over the first and second transistor gate stack and adjacent spacers;
isotropically etching the cap layer over the first transistor gate stack and adjacent spacer;
anisotropically etching the cap layer over the first transistor gate stack and adjacent spacer;
etching a recess in the first region of the substrate, the recess undercutting at least a portion of the spacer adjacent to the first transistor gate stack.

2. The method of claim 1, wherein the cap layer is etched isotropically with a first plasma of a gas mixture comprising CF₄, O₂ and at least one dilution gas selected from the group consisting of Ar, Xe and He.

3. The method of claim 2, wherein the plasma etch condition further comprises between 3 sccm and 10 sccm of O₂ and between 20 sccm and 100 sccm of CF₄ at a pressure between 10 mT and 30 mT and energized with a source power of between 500 W and 1500 W for a chamber adaptable to a 300 mm substrate.

4. The method of claim 1, wherein the cap layer is etched anisotropically with a second plasma of a gas mixture comprising CF₄ and Cl₂.

5. The method of claim 4, wherein the second plasma further comprises a CF₄ to Cl₂ flow rate ratio between 0.5 and 2.

6. The method of claim 5, wherein the second plasma has a process pressure between 4 mT and 10 mT and is energized with a source power of between 500 W and 1500 W for a chamber adaptable to a 300 mm substrate.

7. The method of claim 1, wherein the cap layer is isotropically etched before the cap layer is anisotropically etched.

8. The method of claim 1, wherein the recess is etched with a third plasma of a gas mixture comprising NF₃, Cl₂, O₂, and a dilution gas selected from the group consisting of Ar, Xe and He.

9. The method of claim 8, wherein the third plasma further comprises an NF₃ to Cl₂ flow rate ratio between 0.5 and 1.

10. The method of claim 9, wherein the NF₃ has a flowrate between 25 and 50 sccm, the Cl₂ has a flowrate between 25 and 50 sccm, the O₂ has a flow rate between 5 and 10 sccm and the dilution gas has a flow rate between 100 to 300 sccm.

11. The method of claim 8, wherein the third plasma has a process pressure is between 15 mT and 20 mT.

12. The method of claim 8, wherein the third plasma is energized with a source power of between 600 W and 800 W and a bias power below 100 W, for a chamber adaptable to a 300 mm substrate.

13. A method of plasma etching a recess in a silicon substrate, comprising:
providing the substrate in a plasma etch chamber; and
exposing the substrate to a plasma of a gas mixture comprising NF₃, Cl₂, O₂, and a dilution gas selected from the group consisting of Ar, Xe and He.

14. The method of claim 13, wherein the plasma further comprises a NF₃ to Cl₂ flow rate ratio between 0.5 and 1.

15. The method of claim 13, wherein the NF₃ has a flowrate between 25 and 50 sccm, the Cl₂ has a flowrate between 25 and 50 sccm, the O₂ has a flow rate between 5 and 10 sccm and the dilution gas has a flow rate between 25 sccm to 300 sccm.

16. The method of claim 13, wherein the plasma has a process pressure is between 15 mT and 20 mT.

17. The method of claim 13, wherein the plasma is energized with a source power of between 600 W and 800 W and a bias power below 100 W in a chamber adaptable to a 300 mm substrate.

18. A computer-readable medium having stored thereon a set of machine-executable instructions that, when executed by a data-processing system, cause a system to perform a method comprising:
etching a recess in a silicon substrate with a plasma of a gas mixture comprising NF₃, Cl₂, O₂, and a dilution gas selected from the group consisting of Ar, Xe and He, the gas mixture controlled to a pressure between 15 mT and 20 mT and excited by a source power between 500 W and 1500 W.

19. The computer-readable medium of claim 18, comprising a set of machine-executable instructions that, when executed by a data-processing system, cause a system to perform a method wherein a flow rate NF₃ to Cl₂ ratio is controlled to between 0.5 and 1.

20. The computer-readable medium of claim 18, comprising a set of machine-executable instructions that, when executed by a data-processing system, cause a system to perform a method further comprising:
anisotropically etching a cap layer over the silicon substrate with a second plasma prior to etching the recess in the silicon substrate with a first plasma; and
isotropically etching the cap layer in a first plasma prior to anisotropically etching the cap layer, wherein the isotropic etch, anisotropic etch and recess etch all occur in the same plasma etch chamber.

21. An apparatus comprising:
a p-MOS transistor including:
a gate stack and an adjacent nitride spacer, the adjacent nitride spacer having a cap layer spacer on the sidewall opposite the gate stack;
a SiGe source/drain region embedded in a recess formed in a silicon substrate under the cap layer spacer and under at least a portion of the nitride spacer adjacent to the gate stack, wherein the recess profile is re-entrant by less than 10 nm and at least a portion of the recess sidewall is substantially vertical.

22. The apparatus of claim 21, wherein the top 25% of the recess sidewall is substantially vertical.

23. The apparatus of claim 21, wherein the ratio of a vertical depth of the recess to lateral undercut of the recess is between about 1.1 and 2.2.

24. The apparatus of claim 21, wherein the top taper radius is smaller than the bottom taper radius and the bottom taper radius is less than 50% of the recess depth.

25. The apparatus of claim 21, further comprising:
an n-MOS transistor including:
a gate stack; and
an adjacent nitride spacer covered by a cap layer.

26. The apparatus of claim 27, wherein the lateral thickness of the cap layer spacer is less than 50% of the thickness of the cap layer.
